(19) United States
(12) Patent Application Publication
(10) Pub. No.: US 2017/0104064 A1
(43) Pub. Date: Apr. 13, 2017

(54) Nitride semiconductor device with asymmetric electrode tips

(71) Applicant: SANKEN ELECTRIC CO., LTD., Niiza-Shi (JP)

(72) Inventors: Hironori Aoki, Asaka-shi (JP); Shuichi KANEKO, Yoshikawa-shi (JP)

(21) Appl. No.: 14/880,056

(22) Filed: Oct. 9, 2015

(51) Int. Cl. H01L 29/08; H01L 29/06; H01L 29/778

(52) U.S. Cl. CPC H01L 29/0847; H01L 29/778; H01L 29/0696

(57) ABSTRACT

Nitride semiconductor devices having interdigitated array source and drain electrodes arranged like crossed fingers are described. The electric fields extended at the tips of the array electrodes are relaxed. Desirably, the rounded source electrode tip ends have a larger effective diameter than the rounded tip ends of the drain electrodes. Devices constructed accordingly have higher withstand voltages.

### FIELD The invention relates to transistor electrode structures and particularly to high electron mobility transistors having high breakdown voltage.

### BACKGROUND

Nitride semiconductors often are used for manufacture of power devices with high breakdown voltages because of inherent advantages from this material. A typical nitride semiconductor may be represented by the formula Aluminum-x Indium-y Gallium1-x-y Nitride (0<=x<=1, 0<=y<=1, 0<=x+y<=1), and includes for example gallium nitride (GaN), an aluminum nitride (AlN), and indium nitride (InN). A particularly useful type of nitride semiconductor device often is a high electron mobility transistor, wherein a hetero-junction surface is formed in the interface between a carrier running layer, which consists of a nitride semiconductor which differs in bandgap energy mutually, and a carrier feed layer. In this example, a two-dimensional carrier gas layer as a current path (channel) is formed in the carrier running layer near the hetero-junction surface.

A recent electrode configuration arrangement for a transistor is the tandem-type structure in which the source diffusion area and the drain diffusion region mutually intermingle in an opposing comb structure. The tandom structure of a drain diffusion region and a source diffusion area in interleaving fingers provides several advantages. For example, this has been proposed to lengthen the drift region length near the electrical tip of the teeth of a comb and thereby increase the breakdown voltage of the horizontal-type semiconductor device arranged in the shape of an intersection finger. See JP2001-7339A, the contents of which, and particularly the structural and chemical details for fabrication of High Electron Mobility Transistor (HEMT) devices taught therein, are particularly incorporated by reference in its entirety.

This reference describes changing the form of a diffusion region of a HEMT transistor structure. The proposed design, which makes a two-dimensional carrier gas layer a channel, as described therein, has a thematic voltage limitation. The HEMT has a two-dimensional carrier gas layer as a channel and lacks an ability to control the withstand voltage by varying the shape of the diffusion region.

To improve device performance, an increase in gate-drain reverse breakdown voltage is generally sought. Various technologies have been developed in this aim, including insulated gate, recessed gate, overlapping gate and field plate over an insulator.

In the field of HEMT construction, field plate development has been active. Saito et al demonstrated that higher breakdown voltages could be achieved by connecting a field plate to the source electrode, for example (IEDM Tech. Dig. 2003 pp. 587-590). Also see Xing et al. review of field plate potentiated increase in breakdown voltage (IEEE Electron Device Letters, Vol. 25. No. 4 April 2004. However, these teachings emphasize square electrodes and symmetrical field plates. See for example U.S. Pat. No. 8,754,496. which teaches the desirability of positioning a gate field plate equadistantly from the source electrode and the drain electrode.

The problem of controlling the withstand voltage in interdigitated electrode structures has been addressed in JP publication 2013-98222. This publication concerns a HEMT structure that provides some relaxation of the electric field, and thereby increases the breakdown voltage. Source and drain electrodes of the comb are arranged in the exchanged interdigital structure as shown therein and as represented as FIG. 1.

FIG. 1 shows source electrode region 3, drain electrode region 4 and gate region 5 as interleaving comb fingers with gate between them. This figure shows drain electrode and source electrode widths the same. This drawing shows curved tips wherein the source electrode tips and drain electrode tips have the same radius of curvature, as shown in the circled regions 13 and 14. The cross section at A-A is the same throughout the linear regions but the ends differ. The end curvature is measured with respect to the linear region. The end cross section at B-B differs from the end cross section at C-C by presenting the source electrode on the outside perimeter versus the drain electrode on the outside perimeter. However, threshold voltage limitations remain and it is difficult to relax the electric field well. This reference is also incorporated by reference in its entirety, and particularly the structures and methods for making HEMT devices taught therein.

Maximum operation voltage is often an important constraint in this field and anything that allows an increased voltage during use would provide significant benefits.

### BRIEF DESCRIPTION OF THE DRAWINGS

FIG. 1. This is a plan view of an HEMT device and shows a basic useful construction when the source and drain electrodes are symmetrical (equal configuration).

FIG. 2. This is a plan view of an embodiment.

FIG. 3. This is a cross sectional view showing basic construction of a linear region of a finger for a nitride semiconductor embodiment.

FIG. 4A is a top view of source electrode tip at a concave drain electrode and FIG. 4B is of a drain electrode tip at a concave source electrode.

FIG. 5. This is a plan view of a construction at a source finger tip region.

FIG. 6. This is a plan view of a construction at a drain finger tip region.

### DETAILED DESCRIPTION

An object of embodiments is to provide semiconductor devices with greater withstand voltage by having interdigitated source electrode and a drain electrode tip structures, which provide improved electric field gradients at the tips. It was found that arranging source electrode tips with greater radius of curvature than that of the drain source electrode tips allows improved withstand voltage performance. This astonishing structural feature can provide much higher device withstand voltage performance, which is particularly useful for higher voltage or power applications. As a result, this structure alleviates many of the problems mentioned above in the art. This embodiment can prevent concentration of electric field at the arc portion, which leads to voltage breakdown of the device. In addition, because the opposing electrode side can be thin, the embodiment improves the area efficiency.

An embodiment is a semiconductor device, comprising a substrate base; a nitride semiconductor layer on the substrate base, comprising a laminated carrier supply layer and carrier transit layer region with a formed heterojunction therefrom; an insulating film disposed on the nitride semiconductor layer; a source electrode of a comb shape having a plurality of teeth portions with tips, disposed on the nitride semiconductor layer; a drain electrode of a comb shape having a plurality of teeth portions with tips disposed on the nitride semiconductor and interdigitated with the source electrode; and a gate electrode disposed on the nitride semiconductor layer between the source electrode and the drain electrode, wherein the tips of the source electrode and the tips of the drain electrode are semi-circular shaped, and the radius of curvatures of the source electrode tips are larger than the radius of curvatures of the drain electrode tips. In an embodiment the curvature radius of the source electrodes are from 1.5 to 6 times the radius of curvature of the drain electrodes. In an embodiment the curvature radius of the source electrodes are from 2 to 4 times the radius of curvature of the drain electrodes. In an embodiment the vertical thickness of the drain electrodes is from 1.5 to 6 times the vertical thickness of the source electrodes. In an embodiment the vertical thickness of the drain electrodes is from 2 to 4 times the vertical thickness of the source electrodes. In an embodiment the average width of the source electrodes is between 1.5 and 6 times the average width of the drain electrodes. In an embodiment the average width of the source electrodes is between 2 and 4 times the average width of the drain electrodes. In an embodiment the sides of the tips of the source electrodes are beveled at a slope of at least 10 degrees. In an embodiment the ratio of length to average width of the source electrodes is between 3 and 10. In an embodiment the average width of the drain electrodes is less than 4 mm. In an embodiment the average width of the drain electrodes is 2 mm or less. In an embodiment the device has a breakdown voltage that exceeds 600 volts.

An embodiment is a semiconductor device, comprising: a semiconductor heterojunction layer; an insulating film disposed on the heterojunction layer; a source electrode of a comb shape having a plurality of teeth portions with tips, disposed on the heterojunction layer: a drain electrode of a comb shape having a plurality of teeth portions with tips disposed on the heterojunction layer and interdigitated with the source electrode; and a gate electrode disposed on the heterojunction layer between the source electrode and the drain electrode, wherein the tips of the source electrode and the tips of the drain electrode are semi-circular shaped, and the radius of curvatures of the source electrode tips are larger than the radius of curvatures of the drain electrode tips.

Another embodiment is a HEMT semiconductor device, comprising: a semiconductor heterojunction layer: an insulating film disposed on the heterojunction layer: a source electrode of a comb shape having a plurality of teeth portions with tips, disposed on the heterojunction layer; a drain electrode of a comb shape having a plurality of teeth portions with tips disposed on the heterojunction layer and interdigitated with the source electrode; a gate electrode disposed on the heterojunction layer between the source electrode and the drain electrode, and a gate electrode field plate extending asymmetrically preferentially towards the drain electrode regions of the tips of the drain electrode; wherein the tips of the source electrode and the tips of the drain electrode are semi-circular shaped, and the radius of curvatures of the source electrode tips are larger than the radius of curvatures of the drain electrode tips.

Other embodiments will become apparent to a skilled reader.

Basic Structure: Interdigitated Drain Electrodes with Source Electrodes Having Larger Curved Tips

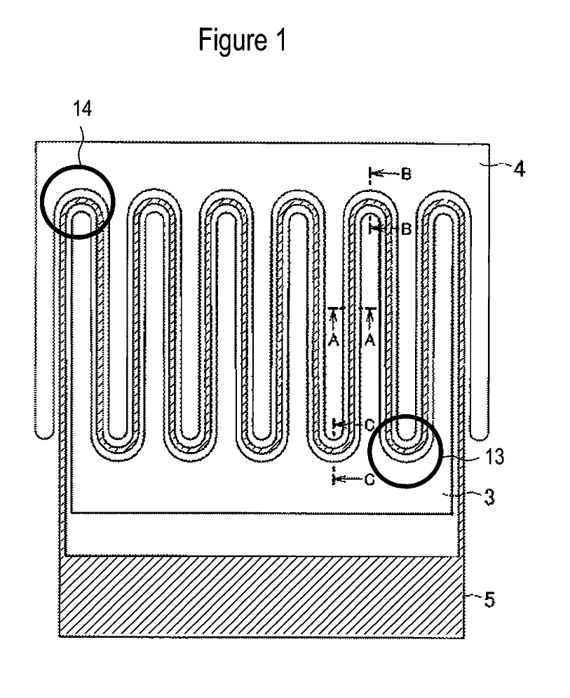

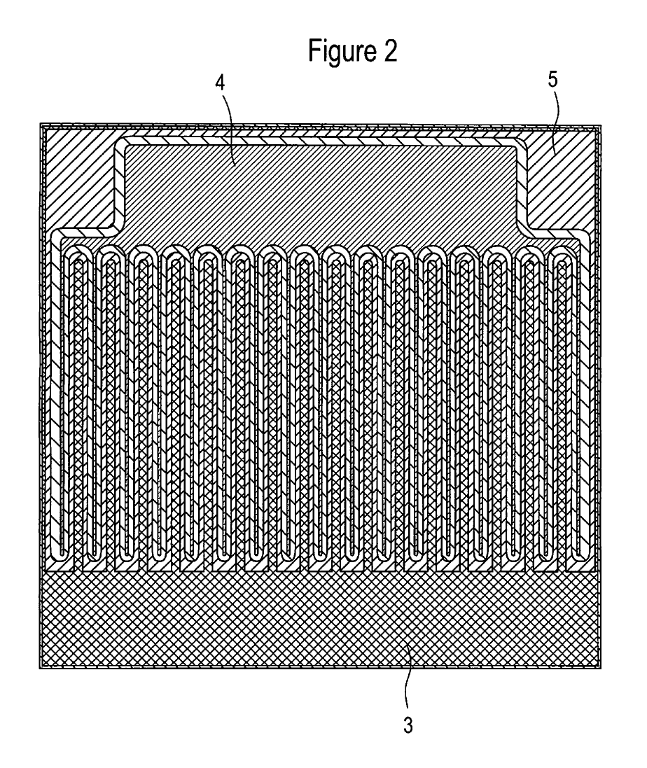

A basic structure is an electric field device such as a FET that has a drain, a source and a gate. For higher current, such devices often have interdigitated (comb-like) source and gate structures. A preferred embodiment is a high electron mobility transistor (“HEMT”) having curved tip structures to relax the electric field impressed by the source (in electron emission as N-doped) onto the semiconductor. The source electrode and drain electrode are comb-shaped and arranged in an interdigital configuration as shown in FIG. 1 and FIG. 2.

Preferably the drain and source electrode tips are curved and each has a radius of curvature. For example drain tip 13 and source tip 14 shown in FIG. 1 each have a characteristic radius of curvature determined as the radius of an arc associated with that tip end surface. In the event the tip is not a semi circle but instead a different curved shape, the radius of curvature is determined by taking the distance from the side to the middle of the long axis of the electrode finger (both values from the linear region).

In most preferred embodiments, the radius of curvature of the drain electrode tip is smaller than the radius of curvature of the source electrode tip. If the source is an inverse (concave surface) arc, curvature may be small because the electric field is not that concentrated. FIG. 2 exemplifies source electrodes that are 2.5 times broader than drain electrodes. Not shown are the field plates. In an embodiment a field plate such as a gate electrode field plate is asymmetrical with respect to neighboring source tip electrodes versus neighboring drain tip electrodes in a similar manner as described for the asymmetric broadness of the electrode tips in the interdigitated structure.

Without wishing to be bound by any one theory for operation of this embodiment, it is believed that advantageous effects of withstand voltage arise from the fact that the electric field (from electrons of a source in a typical HEMT or from a source in an N-type MOSFET) concentrate on the gate end. The electric field is stronger on the arcuate portion than in the straight portion and tends to protrude as a spike from the end. It is seen that increasing the arcuate curvature contributes to relaxation in the electric field. The gate electrode is close to the source electrode and relaxation of the electric field improves high voltage performance by limiting the electric field intensity.

Embodiments particularly pertain to interdigitated source and drain electrodes with tips that impress electric field gradients at their ends. A large variety of field sensitive devices are contemplated to take advantage of this surprising new discovery. In particular the HEMT structure benefits from the discovery of the asymmetric tip electrode radius structures. The HEMT is described herein to exemplify embodiments but the invention is not necessarily limited to this and can be used, with varying degrees of success with other field sensitive devices that are known or will be developed.

### HEMT Embodiments

Virtually any contemplated or future HEMT device having interdigitated electrodes as described herein can benefit via higher withstand voltage from embodiments. In an embodiment with interdigitated source and drain tips, the source tip radius is larger than the drain tip radius. In another embodiment a source field plate is used and the source field plate radius is interdigitated with a larger tip radius in a similar manner as the source electrode tips. In embodiments the radius measurements and area sizes referred to are parallel to the main two dimensional axis plane of the hetero-junction as will be appreciated from inspection of the figures.

In an embodiment the source field plate is larger than and outside the footprint of the source electrode, such as seen from an above (perpendicular to the heterojunction plane) plan view shown in drawings 1, 2, 4 and 5. In another embodiment the source field plate is approximately (within 20%) of the surface area (seen in plan view) of the source electrode. In yet another embodiment the source field plate area is at least 25% larger (as seen from plan view perpendicular to the interdigitated structure) than the source electrode area.

### Desirable Features

Desirable embodiments comprise a substrate base having a semiconductor layer on the base as described for example in JP 2013-98222. The contents of this reference pertaining to materials and construction of HEMT devices are particularly incorporated by reference in their entireties. Although the heterojunction nitride semiconductor is described as formed on the base substrate, with insulator on top, other configurations are contemplated and will work. For example, as shown in U.S. Pat. No. 9,123,740 entitled “High electron mobility transistors and methods of manufacturing the same,” the channel supply layer may be disposed on an insulation layer that is on a substrate, with a channel layer thereupon. The contents, and particularly the materials and methods described in U.S. Pat. No. 9,123,740 are incorporated by reference herein and constitute representative ways of carrying out embodiments described herein.

In preferred embodiments, source, gate and drain electrodes are formed over a hetero-junction that is made on a substrate. A variety of materials may be used for this and related constructions as follows:

Substrate: The substrate may be for example a silicon (Si) substrate, a silicon carbide (SiC) substrate, an aluminum nitride (AlN) substrate, sapphire, a direct bonded copper (DBC) substrate, and a metal substrate. However, a type of the substrate is not limited thereto, and may vary.

Insulation layer. The insulation layer may be formed of any insulation material, such as at least one of silicon nitride, silicon oxide, silicon oxynitride, aluminum nitride, and aluminum oxide. Also, the insulation layer ID may be formed of an insulative polymer.

Electrodes: A drain electrode, a gate electrode, and a source electrode may be disposed spaced apart from each other in the insulation layer, on the insulation layer, in between insulation layers etc. The drain electrode, gate electrode, and source electrode may be metals or metal compounds, but example embodiments are not limited thereto. For example, source and drain electrodes can be a lamination of a Ti layer that is in contact with the active layer and a layer of alloy Al and Si formed on the Ti layer. A wide variety of gate electrode materials are known such as laminations of for example Ni and

Au.

Heterojunction: For HEMT embodiments, the structure incorporates a junction between two materials with different band gaps (that is, a heterojunction) as the channel instead of a doped region (as is generally the case for a MOSFET). A desirable material combination is GaAs with AlGaAs. However a wide variation of materials are useful, dependent on the application. For example, devices incorporating indium may be used for improved high-frequency performance

The heterojunction exists as a channel supply layer that may be in contact with the gate electrode. The channel layer includes a two-dimensional electron gas (2DEG) induced by the channel supply layer, an effective channel region contacting the channel supply layer, and a high resistivity region on the effective channel region. The high resistivity region is a region in which impurities are (typically) ion-implanted, although chemical vapor deposition and other techniques can be used. The impurities may include for example at least one of neon (Ne), argon (Ar), carbon (C), iron (Fe), and vanadium (V). The impurities may be ion-implanted at a concentration of about 10¹⁵/cm³ to about 10²¹/cm³ in the high resistivity region. The high resistivity region may have a resistivity equal to or greater than about 10⁷ ohm cm. The high resistivity region may extend throughout a top portion of the channel layer. The channel region preferably is about 50 nm to about 200 nm but may be bigger or smaller. The channel layer may include a gallium nitride (GaN)-based material. For example, the channel layer may include GaN.

The channel supply layer may exist as a single or a multi-layer structure. The channel supply layer preferentially includes a nitride that contains at least one of aluminum (Al), gallium (Ga), indium (In), and boron (B). For example, the channel supply layer may include a single and multi-layer structure that includes at least one of AlGaN, AlInN, AlN, AlInGaN, and the like. The channel supply layer, CS1, may induce a two-dimensional electron gas (2DEG) (not shown), in a channel layer, C1, which is formed on the channel supply layer CS1. The channel supply layer, CS1, may include a material having higher polarizability and/or larger energy bandgap than the channel layer, C1. For example, the channel supply layer, CS1, may have a single or multi-layer structure including at least one material selected from among nitrides including at least one of aluminum (Al), gallium (Ga), indium (In), and boron (B). In detail, the channel supply layer CS1 may have a single or multi-layer structure including at least one of various materials consisting of AlGaN, AlInN, AlN, AlInGaN, BN, and so on. The thickness of the channel supply layer, CS1, may be equal to or less than about several tens of nm. For example, the thickness of the channel supply layer, CS1, may be equal to or less than about 50 nm.

The channel layer, C1, may be disposed on the channel supply layer, CS1. The channel layer, C1, may include a material having smaller polarizability and/or energy bandgap than the channel supply layer, CS1. For example, the channel layer, C1, may include a GaN-based material, such as GaN. A 2DEG (not shown) induced by the channel supply layer, CS1, may exist in the channel layer, C1. The 2DEG may be formed in a portion of the channel layer, C1, adjacent to the interface between the channel layer, C1, and the channel supply layer, CS1. The thickness of the channel layer, C1, may be thicker than that of the channel supply layer, CS1. For example, the thickness of the channel layer, C1, may be from about 2 nanometers to about 3 nanometers. However, in some cases, the thickness of the channel layer, C1, may be greater than about 3 nanometers.
Buffer layer. The HEMT may further include a buffer layer on the channel layer. At least a part of the buffer layer may be a region into which the impurities are ion-implanted. The buffer layer B1 may include a transition layer. For example, the buffer layer B1 may have a single or multi-layer structure including at least one material selected from among nitrides including at least one of Al, Ga, In, and B. In detail, the buffer layer B1 may have a single or multi-layer structure including at least one of various materials consisting of AlN, GaN, AlGaN, AlInN, AlGaInN, BN, and so on. The buffer layer B1 may be a region into which the impurities are ion-implanted, like the high resistivity region r2. Accordingly, the buffer layer B1 and the high resistivity region r2 may be together referred to as an ion-implanted region IP1. The HEMT may further include a metal layer between the substrate and the insulation
Field Plates: Preferably one or more of the electrodes include field plates extending over the electrode and separated preferably from the underlying electrode with an insulation layer. Preferably these are sized and positioned asymmetrically with respect to the electrodes, unlike the prior art, which teaches away from this concept as seen, for example in U.S. Pat. No. 8,754,496. Embodiments utilize field plates that are preferred at the gate edge of the drain side (or larger in this region) to limit peak electric field at the drain edge.

In an embodiment, a gate field plate is combined with a larger source electrode radius tip end to synergistically limit peak electric field. In an embodiment the gate field plate shape corresponds (follows the contour of) the source electrode. “Corresponds” in this context means to follow the shape within 50%, preferably within 80% and more preferably within 90%. In an embodiment the gate field plate extends laterally over the heterojunction plane at least 10%, preferably at least 20% and more preferably at least 30% from the area of the underlying gate electrode and asserts such beneficial effect thereby. The percentages referred to here are percent area of the uncovered surface area between the gate electrode and the drain electrode.

Desirably the gate field plate covers at least 10% of the area between the gate electrode and the drain electrode and has a radius that is larger when matched with a source electrode tip inside the interdigitated finger than when matched with a drain electrode tip inside the interdigitated finger. In other words, in an embodiment the gate field electrode has a semi-circular shape with a defined radius of curvature that follows either the gate electrode contours or the drain electrode contours.

The curvature radius of the gate field electrode is greater when surrounding the source electrode than when the gate field electrode is surrounding the drain electrode, as seen in plan view of the interdigitated structure. In an embodiment the asymmetric semi-circular gate field plate as described above is paired with asymmetric semi-circular source electrodes so that an enlarged field gate exists near the tip of the source electrode and a smaller (or no) field electrode exists near the tip of the drain electrode.

In an embodiment source field electrodes are used which are larger at a source electrode tip ends than at the drain electrode tip ends.

### Interdigitated Electrodes and Radius of Curvature

Prior art structures often emphasized sharp edged interdigitated electrodes for economy of space reasons and teach away from inventive concepts apprehended by the inventor. For example U.S. Pat. No. 9,123,740 teaches the desirability of squared off interdigitated electrodes in combination with trench structures for HEMT devices. See for example FIG. 2 from that reference. In contrast, the asymmetric rounded (or other non-sharp edge shaped) tip configuration presented here provides enhanced high voltage resistance.

Preferably the basic interdigitated structure is prepared and used as described in JP publication 2013-98222. However a large variety of devices can utilize the embodiments exemplified here and recited in the claims.

### Versions of HEMTs:

pHEMT embodiments In practice, desirable materials such as AlGaAs on GaAs have lattice constants that generally slightly differ. This results in crystal defects. Embodiments employ a pHEMT or pseudomorphic HEMT wherein this rule is violated by using an extremely thin layer of one of the materials—so thin that the crystal lattice simply stretches to fit the other material. Skilled artisans can readily construct pHEMT devices according to embodiments taught herein and such embodiments and are included.

mHEMT embodiments These include devices that utilize materials of different lattice constants with a buffer layer between them. In a preferred embodiment the buffer layer is made of AlInAs, with the indium concentration graded so that it can match the lattice constant of both the GaAs substrate and the GaInAs channel. This potentiates use of practically any Indium concentration in the channel. Thus devices can be optimized for different applications such as low indium concentration devices that provide low noise performance and high indium concentration devices that provide high gain performance.

Induced HEMT embodiments In contrast to a modulation-doped HEMT, an induced high electron mobility transistor provides the flexibility to tune different electron densities with a top gate, since the charge carriers are “induced” to the 2DEG plane rather than created by dopants. The absence of a doped layer enhances the electron mobility significantly when compared to their modulation-doped counterparts. These induced HEMT devices are intended embodiments as well.

HEMTs and related devices having interdigitated electrode structures can benefit from the asymmetric source and drain electrodes. Examples provided below relate to a wide range of devices. These examples illustrate equipment and methods for materializing the technical idea of embodiments. The technical idea of this invention as recited in the claims does not specify the form of component parts, structure, arrangement, etc. except as illustrated by the following and by what a skilled artisan naturally can determine.

### EXAMPLE

### Construction of Interdigitated HEMT

A preferred basic construction is taught in JP publication 2013-98222. See FIG. 1 and associated text from this publication, which describes preferred dimensional ratios for the electrodes shown. The relationships taught therein are preferred with adoption of asymmetric tips taught herein. A brief summary is presented here. Details of HEMT construction from this reference are particularly incorporated by reference and briefly mentioned here in the context of using altered, more advantageous electrode tip end structures as shown in FIG. 2.

A nitride semiconductor device is provided with a gate electrode 5 arranged between source electrode 3 and drain electrode 4. This configures a tandem-type form having multiple gear-tooth portions mutually extended in a vertical direction toward a side as shown in FIG. 2. FIG. 2 shows respectively, and the source electrode 3 and the drain electrode 4. The gear-tooth portion of the comb of the source electrode 3 and the drain electrode 4 are arranged in the shape of intersecting fingers. That is, each gear-tooth portion of the drain electrode is arranged between gear-tooth portions of source electrode 3. For this reason, gate electrode 5 is arranged so that it may overlap with right and left directions toward the side of the figure as shown.

Each electrode region is a “linear” region or an end “proximal” region. A “linear” region is defined as the region where the gear-tooth portions of the source electrode 3 and the drain electrode 4 are linearly co-parallel. A “proximal” region, otherwise termed a “point” herein, is the region of a point, of the gear-tooth portions of the source electrode 3 and the drain electrode 4 whose outer edge is a curve.

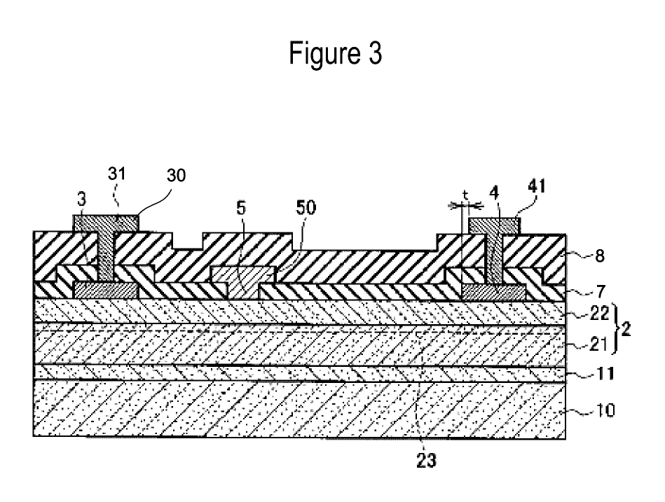

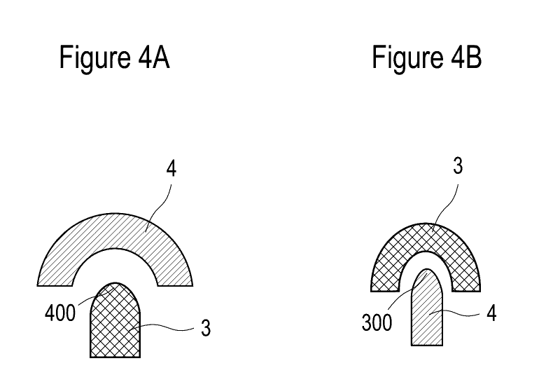

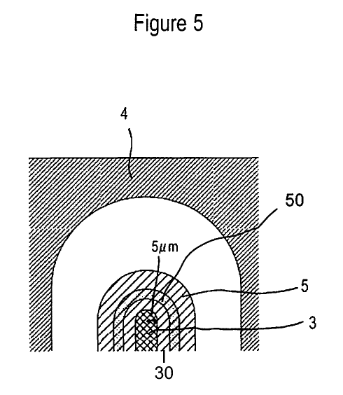

FIG. 3 shows a cross section of the device taken along the extending direction of the gear-tooth portions of the source electrode 3 and the drain electrode 4 in the linear area of the source electrode 3 and the drain electrode 4. The cross.section will differ at the alternative drain versus source tip ends, as will be explained later with respect to FIGS. 4 and 5.

Notably, the distances between regions preferably may be altered as described in JP 2013-98222. Looking at a cross section via FIG. 3, nitride semiconductor layer 20 is a lamination 20 of carrier running layer 21 in which the nitride semiconductor device 1 forms the carrier feed layer 22 and the carrier feed layer 22. This is the hetero-junction as part of an HEMT, which further consists of insulator layer 7 arranged on the nitride semiconductor layer 20. Source electrode 3, the drain electrode 4, and the gate electrode 5 are arranged on nitride semiconductor layer 20. The insulator layer 7 covers the source electrode 3 and the drain electrode 4, and is arranged, and as the opening formed in the insulator layer 7 is embedded, the gate electrode 5 is arranged. Interlayer insulation film 8 is arranged on the gate electrode 5 and the insulator layer 7, the source electrode wiring 31 is connected with the source electrode 3 respectively via the opening formed in the interlayer insulation film 8, and the drain electrode wiring 41 is connected with the drain electrode 4.

The nitride semiconductor device is further provided with gate field plate 50 electrically connected with gate electrode 5, and source field plate 30 electrically connected with source electrode 3. This arrangement of gate field plate 50 and source field plate 30 between gate electrode 5 and drain electrode 4 controls curvature of the depletion layer of the drain side end of the gate electrode 5. Also this eases the concentration of the bias electric fields at the end on the drain electrode side of the gate electrode 5 (herein termed “drain side end”.)

As shown in FIG. 3, gate field plate 50 is connected with the upper end part of gate electrode 5, and is arranged on insulator layer 7 between gate electrode 5 and drain electrode 4. Gate field plate 50 electrically connects with source electrode 3 via source electrode wiring 31, and source field plate 30 is arranged on the interlayer insulation film 8 so that it may oppose nitride semiconductor layer 2 via insulator layer 7 and interlayer insulation film 8 between the gate field plate 50 and drain electrode 4. In the example shown in FIG. 3, the region extended to the drain electrode side of source electrode wiring 31 functions as source field plate 30. In an embodiment, this overhanging edge at the top right side of 31 extends further than that shown here, towards gate 5. In FIG. 2 the graphic display of gate field plate 50 and source field plate 30 is omitted.

As shown in FIG. 3, buffer layer 11 is arranged on substrate 10, and nitride semiconductor layer 20 is arranged on buffer layer 11. The specific constructional example of this representative nitride semiconductor device is mentioned below.

The shapes of the tip of source electrode 3, the tip of drain electrode 4, and the source field plate 30 are semicircular. Each semicircular shape has a characteristic radius that is easily measured from the respective cross section edges. Most importantly, the semicircular radius of the source electrode is larger than the semicircular radius of the drain electrode. In other optional embodiments, the shapes depart from strictly semicircular, but preferably the ends are curved. Preferably the average width of the source electrodes is at least 50% greater than the average width of the drain electrodes, regardless of the exact shape. More preferably the average width is at least twice the average width of the drain electrodes.

In the source proximal region, the outer edge of the handle portion between the gear-tooth portions of the drain electrode 4 has become depressed in a preferred semicircular shapes along the tip of the source electrode 3. Similarly, in the drain proximal region, the outer edge of the handle portion between the gear-tooth portions of the source electrode 3 has become depressed in preferably semicircular shapes along the tip of the drain electrode 4. For this reason, the gate electrode 5 arranged between the source electrode 3 and the drain electrode 4 is preferably a circular shape in a proximal region. Similarly, the gate field plate 50 and the source field plate 30 are also preferably circular shape in a proximal region.

### Preferred Source and Drain Electrode Tip Configurations

The embodiments described herein most preferably further include asymmetric source electrode tip size vs drain electrode tip size. As shown in FIG. 4A, drain electrode 4 on top has curvature with a concave cavity that is barely (less than 10%, preferably less than 1%) penetrated by the tip 400 of the source electrode shown below in this drawing. On the other hand, as shown in FIG. 4B, the source electrode 3 at the top of this drawing has a curvature with a concave cavity that is significantly (at least 20%, preferably at least 33% and more preferably at least 50%) penetrated by the tip 300 of the drain electrode.

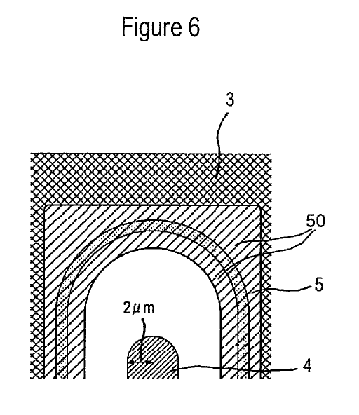

A more detailed representation of this tip asymmetry is shown in plan views FIGS. 5 and 6. An enlarged drawing of a source proximal region is shown in FIG. 5, and an enlarged drawing of a drain proximal region is shown in FIG. 6, respectively. In FIG. 5 and FIG. 6, the upper layer is ignored and source electrode 3, drain electrode 4, gate electrode 5, and gate field plate 50 are illustrated.

FIG. 5 shows a top down view of a source electrode tip 400 extending as a comb finger into a drain electrode region 4. The source electrode width shown here as horizontal arrows is 10 microns wide and has a 5 micron tip radius. The source electrode proximal tip region penetrates the gate electrode tip curvature axis here, as a preferred embodiment.

FIG. 6 shows a top down view of a drain electrode tip 300 extending as a comb finger into source electrode region 3. The drain electrode width shown here is 4 microns wide and has a 2 micron tip radius. The drain electrode proximal tip region does not penetrate the gate electrode tip curvature axis here, as a preferred embodiment.

The actual dimensions of the linear regions (not shown in FIGS. 5 and 6) versus non-linear (preferably semicircular curved) proximal regions, the ratio between them and the distances between the electrodes may be altered. A skilled artisan readily may alter these ratios as is known in the literature and as exemplified in JP publication 2013-98222, which shows ratios in FIG. 3(a) and FIG. 3(b) of this publication, distance LGSa, LGSb, and LGSc. This publication shows distance (“distance between G_S”). LGS between the source side end of the gate electrode 5 and the gate electrode side end of the source electrode 3 in each of a linear area, a source proximal region, and a drain proximal region. Distance LGDa, LGDb, and LGDc are defined and guidance given. The “distance between G_D” is explained below. LGD is between the drain side end of the gate electrode 5 and the gate electrode side end of the drain electrode 4 in each of a linear area, a source proximal region, and a drain proximal region. Distance LGFPa, LGFPb, and LGFPc, It is distance (“distance between G_GF” is told to below.) LGFP between the drain side end of the gate electrode 5, and the drain side end of the gate field plate 50 in each of a linear area, a source proximal region, and a drain proximal region. Distance LGFP is between G_GF and is equivalent to the length of the gate field plate 50. Distance LSFPa is distance (“distance between GF_SF” as explained below.) LSFP is between the drain side end of the gate field plate 50, and the drain side end of the source field plate 30 in each of a linear area, a source proximal region, and a drain proximal region. Distance LSFP between GF_SF is equivalent to the length of the source field plate 30.

As shown in FIG. 3(a) and FIG. 3(b) of the reference, distance LGSb between G_S in a source proximal region and a drain proximal region and LGSc are longer than distance LGSa between G_S in a linear area. Similarly, distance LGDb between G_D in a source proximal region and a drain proximal region and LGDc are longer than distance LGDa between G_D in a linear area. Distance LGFPb between G_GF in a source proximal region and a drain proximal region and LGFPc are longer than distance LGFPa between G_GF in a linear area. Distance LSFPb between GF_SF in a source proximal region and a drain proximal region and LSFPc are longer than distance LSFPa between GF_SF in a linear area.

It is preferable to make the gate length of a proximal region longer than the gate length of a linear area in addition to each of above-mentioned distances. The actual ratio of linear region to proximal region and the number of fingers in a comb will vary depending on the desired operation speed and other variables as a skilled artisan readily will recognize.

### Source Electrode Proximal Radius Exceeds Drain Electrode Proximal Radius

FIG. 2 shows an embodiment that relies on the general structure described immediately above wherein each source proximal region is larger than each drain proximal region. This comb structure shows equal length drain electrode fingers and source electrode fingers. However, the lengths can be different. For example the source electrode fingers can be shorter with broader tips, while the drain electrode fingers can be longer. FIG. 2 shows a ratio of source electrode width to drain electrode tip of 2.5 to 1. Other ratios such as 1.5 to 1, 2 to 1, 3 to 1, 4 to 1 and ranges within these are useful as well.

The average length to average width ratio of the electrode fingers may be for example between 3 and 10. The average width of the drain electrodes can be less than 4 mm, less than 3 mm, less than 2 mm, or even less than 1.5 mm. The tips of the electrodes may be beveled due to isotropic etching or other formation process to a slope of at least 5 degrees, at least 10 degrees, at least 15 degrees or more. In a preferred embodiment the source electrodes are wider than the drain electrodes, as for example shown in the interdigitated structure of FIG. 2. In this case, preferably the drain electrodes are commensurately thicker (deeper in the plane perpendicular to the hetero-junction layer). For example the vertical thickness of the drain electrodes may be from 2 fold to 4 fold that of the source electrodes.

### Construction of a Typical Device

A specific construction of a nitride semiconductor device is described next.

A semiconductor substrate is used such as a silicon (Si) substrate, a silicon carbide (SiC) substrate, and a GaN substrate, silicon on sapphire or a ceramic substrate. See FIG. 3. The buffer layer 11 can be formed with epitaxial grown methods, such as an organic-metal-vapor-growth (MOCVD) method. Although the buffer layer 11 is illustrated as one layer, the buffer layer 11 may be formed in a plurality of layers. For example, also acceptable is a multilayer-structure buffer which laminated alternately the first sublayer (first sublayer) and that consists of an aluminum nitride (AlN), and a second sublayer (second sublayer) which consists of GaN. Since the buffer layer 11 is not directly related to operation of HEMT, the device may exclude the buffer layer 11. It can also be considered that the structure which combined the substrate 10 and the buffer layer 11 is a substrate. The structure of the buffer layer 11 and arrangement are determined according to the material of the substrate 10.

The nitride semiconductor layer 2 has the carrier feed layer 22 which consists of a first nitride semiconductor layer, and the carrier running layer 21 which consists of a second nitride semiconductor layer which has different bandgap energy from a first nitride semiconductor layer.

The carrier running layer 21 arranged on the buffer layer 11 is grown epitaxially as non-doped GaN, for example by an organic-metal-vapor-growth (MOCVD) method. Non-doped in this context means that the impurity is not added intentionally.

A band gap is larger than the carrier running layer 21, and the carrier feed layer 22 arranged on the carrier running layer 21 consists of a nitride semiconductor whose lattice constant is smaller than the carrier running layer 21. AluminumxGa1-xN non-doped as the carrier feed layer 22 can be used.

The carrier feed layer 22 is formed on the carrier running layer 21 by epitaxial growth by an MOCVD method etc. Since a lattice constant differs between the carrier feed layer 22 and the carrier running layer 21, piezo polarization is produced by a lattice strain. A high-density carrier arises in the carrier running layer 21 near the hetero-junction, and the two-dimensional carrier gas layer 23 as a current path (channel) is formed in it by this piezo polarization and the spontaneous polarization of the crystal of the carrier feed layer 22.

The source electrode 3 and the drain electrode 4 are formed of metal that allows low resistance contact with nitride semiconductor layer 2. For example, aluminum (aluminum), titanium (Ti), etc. can be used for the source electrode 3 and the drain electrode 4. Alternatively a laminated body of Ti and aluminum can be used for the source electrode 3 and the drain electrode 4.

Nickel gold (NiAu) etc. are employable as the gate electrode 5 and the gate field plate 50, for example, aluminum metallurgy (Au), copper (Cu), etc. are employable as the source electrode wiring 31 and the drain electrode wiring 41, for example.

Insulation layers can be added as needed, as will be appreciated by a skilled artisan.

Other embodiments not described herein will be understood by a skilled reader and are included within the ambit of the attached claims, as space limitations preclude adding additional information that is readily available.

1. A semiconductor device, comprising:
a substrate base;
a nitride semiconductor layer on the substrate base, comprising a laminated carrier supply layer and carrier transit layer region with a formed heterojunction therefrom;
an insulating film disposed on the nitride semiconductor layer;
a source electrode of a comb shape having a plurality of teeth portions with tips, disposed on the nitride semiconductor layer;
a drain electrode of a comb shape having a plurality of teeth portions with tips disposed on the nitride semiconductor and interdigitated with the source electrode; and
a gate electrode disposed on the nitride semiconductor layer between the source electrode and the drain electrode, wherein
the tips of the plurality of teeth portions of the source electrode and the tips of the plurality of teeth portions of the drain electrode are semi-circular shaped, and the radius of curvatures of the tips of plurality of teeth portions of the source electrode are larger than the radius of curvatures of the tips of plurality of teeth portions of the drain electrode.

2. The semiconductor device of claim 1, wherein
the curvature radius of the tips of plurality of teeth portions of the source electrode are from 1.5 to 6 times the radius of curvature of the tips of plurality of teeth portions of the drain electrode.

3. (canceled)

4. The semiconductor device of claim 1, wherein the average width of the plurality of teeth portions of the source electrode is between 1.5 and 6 times the average width of the plurality of teeth portions of the drain electrode.

5. The semiconductor device of claim 1, wherein the sides of the tips of the plurality of teeth portions of the source electrode are beveled at a slope of at least 10 degrees.

6. The semiconductor device of claim 1, wherein the ratio of length to average width of the plurality of teeth portions of the source electrode is between 3 and 10.

7. The semiconductor device of claim 2, wherein the average width of the plurality of teeth portions of the drain electrode is less than 4 mm.

8. The semiconductor device of claim 2, wherein the average width of the plurality of teeth portions of the drain electrode is 2 mm or less.

9. The semiconductor device of claim 1, having a breakdown voltage that exceeds 600 volts.

10. A semiconductor device, comprising:
a semiconductor heterojunction layer;
an insulating film disposed on the heterojunction layer;
a source electrode of a comb shape having a plurality of teeth portions with tips, disposed on the heterojunction layer;
a drain electrode of a comb shape having a plurality of teeth portions with tips disposed on the heterojunction layer and interdigitated with the source electrode; and
a gate electrode disposed on the heterojunction layer between the source electrode and the drain electrode, wherein
the tips of the plurality of teeth portions of the source electrode and the tips of the plurality of teeth portions of the drain electrode are semi-circular shaped, and the radius of curvatures of the tips of the plurality of teeth portions of the source electrode are larger than the radius of curvatures of the tips of the plurality of teeth portions of the drain electrode.

11. The semiconductor device of claim 10, wherein
the curvature radius of the tips of plurality of teeth portions of the source electrode are from 1.5 to 6 times the radius of curvature of the tips of it of teeth portions of the drain electrode

12. (canceled)

13. The semiconductor device of claim 10, wherein the average width of the pluralitu of teeth portions of the source electrode is between 1.5 and 6 times the average width of the plurality of teeth portions of the drain electrode.

14. An HEMT semiconductor device, comprising:
a semiconductor heterojunction layer;
an insulating film disposed on the heterojunction layer;
a source electrode of a comb shape having a plurality of teeth portions with tips, disposed on the heterojunction layer;
a drain electrode of a comb shape having a plurality of teeth portions with tips disposed on the heterojunction layer and interdigitated with the source electrode;
a gate electrode disposed on the heterojunction layer between the source electrode and the drain electrode, and
a gate electrode field plate extending asymmetrically preferentially towards the drain electrode regions of the tips of the drain electrode; wherein
the tips of the plurality of teeth portions of the source electrode and the tips of the plurality of teeth portions of the drain electrode are semi-circular shaped, and the radius of curvatures of the tips of the plurality of teeth portions of the source electrode are larger than the radius of curvatures of the tips of the plurality of teeth portions of the drain electrode.
